(19) United States
(12) Patent Application Publication
(10) Pub. No.: US 2006/0113659 A1
(43) Pub. Date: Jun. 1, 2006

(54) Pulse transformer package and method for making the same

(76) Inventors: Chi-Tsai Liu, Feng Shan City (TW); Mao-Shin Hsieh, Feng Shan City (TW); Ko-Lin Hung, Feng Shan City (TW); Hui-Min Yu, Feng Shan City (TW)

Correspondence Address: HARNESS, DICKEY & PIERCE, P.L.C., P.O. BOX 8910, RESTON, VA, 20195, US

(21) Appl. No.: 10/998,944

(22) Filed: Nov. 30, 2004

(51) Int. Cl. H01L 21/48; H01L 23/52

(52) U.S. Cl. 257/704; 438/125; 257/698; 257/924

(57) ABSTRACT

A pulse transformer package includes a substrate, a passive component, and a cap member. The substrate includes a surface layer, a base layer, a middle wiring layer between the surface and base layers, a set of bonding pads formed on the surface layer, and a set of connecting pads formed on the base layer. The bonding pads and the connecting pads are connected electrically to the wiring layer. The passive component is connected electrically to the bonding pads on the substrate. The cap member is connected to the surface layer of the substrate, and cooperates with the surface layer to form a sealed space for the passive component.

### BACKGROUND OF THE INVENTION

1. Field of the Invention

The invention relates to a transformer suitable for use as a noise filter, more particularly to a pulse transformer package and method for making the same.

2. Description of the Related Art

Pulse transformers are commonly employed in communications devices to filter out noise. Referring to FIG. 1, a conventional pulse transformer package 1 suitable for use as a noise filter in communications devices is shown to include a lead frame 11 and a passive component 12.

The lead frame 11 includes two sets of terminals 112 on opposite sides of the pulse transformer package 1. Each terminal 112 has a stepped configuration, and includes an inner connecting section 113, an outer connecting section 114, and a bridging section 115 that interconnects the inner and outer connecting sections 113, 114.

The passive component 12 is a pulse transformer component that includes a plurality of windings 121 on a transformer core. The windings 121 are connected electrically to the inner connecting sections 113 of the terminals 112 by means of wires 13, which also serve to fix the passive component 12 on the lead frame 11.

A packaging body 14, which is formed from a dielectric molding compound, is used to enclose the passive component 12, the wires 13 and the inner connecting sections 113 of the terminals 112, while leaving the bridging sections 115 and the outer connecting sections 114 of the terminals 112 exposed. As a result, the outer connecting sections 114 of the terminals 112 can be mounted on a circuit board (not shown) when the pulse transformer package 1 is in use.

During mass production, the packaging body 14 is formed after the passive component 12 is connected to the terminals 112 by means of the wires 13 to result in a semi-product. The semi-product is then processed to form the stepped configuration of the terminals 112.

It is known in the art that the outer connecting sections 114 of the terminals 112 must lie on the same plane to ensure proper connection of the pulse transformer package 1 to a circuit board. Hence, an additional step of terminal inspection is required during the mass production of the pulse transformer package 1 to ensure that the outer connecting sections 114 of the terminals 112 indeed lie on the same plane. Thereafter, the pulse transformer packages 1 with the defective terminals 112 further undergo a manual terminal-correction step such the outer connecting sections 114 of the defective terminals 112 of the pulse transformer packages 1 are corrected to lie on the same plane. The inclusion of the terminal inspection and terminal corrections steps in the aforementioned conventional method increases the production cost of the conventional pulse transformer package 1.

### SUMMARY OF THE INVENTION

Therefore, the main object of the present invention is to provide a pulse transformer package that can dispense with the need for terminal inspection and terminal correction steps during the manufacture thereof to result in lower production costs.

Another object of the present invention is to provide a method for making the pulse transformer package of this invention.

According to one aspect of the invention, there is provided a pulse transformer package adapted for mounting on a circuit board to serve as a noise filter. The pulse transformer package comprises a substrate, a passive component, and a cap member.

The substrate includes a surface layer, a base layer, and a middle wiring layer between the surface and base layers. Each of the surface and base layers is made of a dielectric material. The substrate further includes a set of bonding pads formed on the surface layer, and a set of connecting pads formed on the base layer. The wiring layer, the bonding pads and the connecting pads are made of an electrically conductive material. The bonding pads and the connecting pads are connected electrically to the wiring layer. The connecting pads permit mounting of the substrate on the circuit board, and are capable of establishing electrical connection between the wiring layer and the circuit board.

The passive component is connected electrically to the bonding pads on the substrate, thereby establishing electrical connection between the passive component and the wiring layer.

The cap member is connected to the surface layer of the substrate, and cooperates with the surface layer to form a sealed space for the passive component.

According to another aspect of the invention, there is provided a method for making a pulse transformer package that is suitable for mounting on a circuit board. The method comprises the steps of:

a) forming a substrate that includes a surface layer, a base layer, and a middle wiring layer between the surface and base layers, each of the surface and base layers being made of a dielectric material,

the substrate further including a set of bonding pads formed on the surface layer, and a set of connecting pads formed on the base layer,

the wiring layer, the bonding pads and the connecting pads being made of an electrically conductive material,

the bonding pads and the connecting pads being connected electrically to the wiring layer,

the connecting pads permitting mounting of the substrate on the circuit board, and being capable of establishing electrical connection between the wiring layer and the circuit board;

b) connecting a passive component electrically to the bonding pads on the substrate, thereby establishing electrical connection between the passive component and the wiring layer; and

c) mounting a cap member on the surface layer of the substrate such that the cap member cooperates with the surface layer to form a sealed space for the passive component.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of a conventional pulse transformer package;

FIG. 2 is a schematic view of the first preferred embodiment of a pulse transformer package according to the present invention;

FIG. 3 is a flowchart to illustrate the preferred embodiment of a method for making the pulse transformer package of FIG. 2; and

FIG. 4 is a schematic view of the second preferred embodiment of a pulse transformer package according to the present invention.

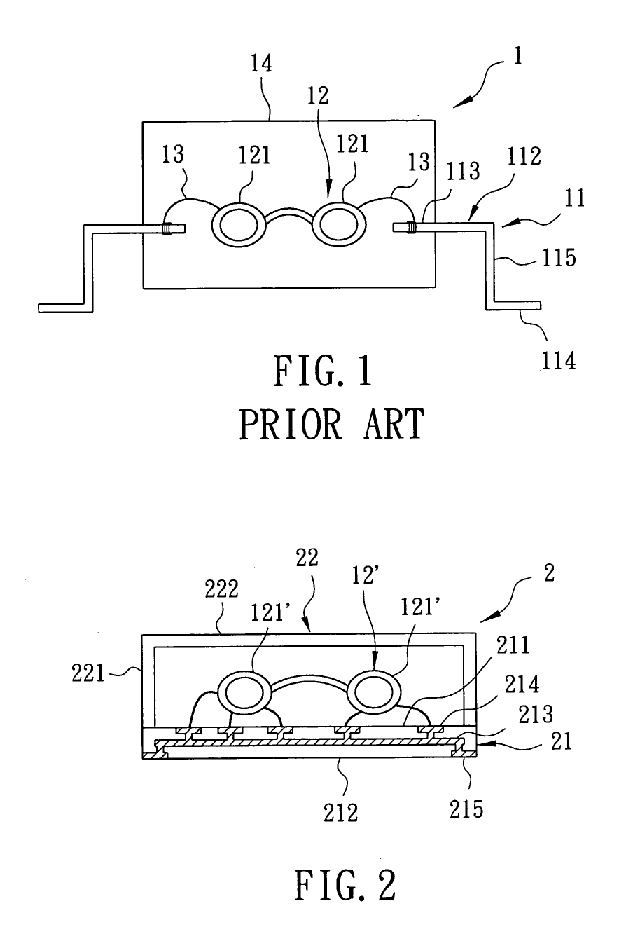

### DETAILED DESCRIPTION OF THE PREFERRED EMBODIMENTS

FIG. 2 illustrates the first preferred embodiment of a pulse transformer package 2 according to the present invention. The pulse transformer package 2 is to be mounted on a circuit board (not shown) of a communications device to serve as a noise filter.

The pulse transformer package 2 includes a substrate 21, a passive component 12′, and a cap member 22.

In this embodiment, the substrate 21 includes a surface layer 211, a base layer 212, and a middle wiring layer 213 sandwiched between the surface and base layers 211, 212. The surface and base layers 211, 212 are made of a dielectric material. The substrate 21 further includes a set of bonding pads 214 formed on the surface layer 211, and a set of connecting pads 215 formed on the base layer 212. The wiring layer 213, the bonding pads 214 and the connecting pads 215 are made of an electrically conductive material, such as copper.

The bonding pads 214 and the connecting pads 215 are connected electrically to wiring tracks of the wiring layer 213. To form the bonding pads 214 and the connecting pads 215, holes are first formed in the surface layer 211 and the base layer 212 to expose parts of the wiring tracks of the wiring layer 213. The holes are then filled with an electrically conductive material, such as by electroplating, to form the bonding pads 214 and the connecting pads 215 that extend into the respective one of the surface layer 211 and the base layer 212 to connect electrically with the wiring tracks of the wiring layer 213. Hence, with the use of solder material, the bonding pads 214 and the connecting pads 215 permit electrical connection between the passive component 12′ and a circuit board (not shown).

The passive component 12′ is a pulse transformer component similar to that employed in the aforementioned conventional pulse transformer package 1, and includes a plurality of windings 121′ on a transformer core. The windings 121′ are connected electrically to the bonding pads 214 on the substrate 21, thereby fixing the passive component 12′ on the substrate 21 and thereby establishing electrical connection between the passive component 12′ and the wiring layer 213.

The cap member 22 includes a cover part 222 and a surrounding wall part 221 having opposite ends connected to the surface layer 211 of the substrate 21 and the cover part 222, respectively. The cap member 22 cooperates with the surface layer 211 of the substrate 21 to form a sealed space for the passive component 12′.

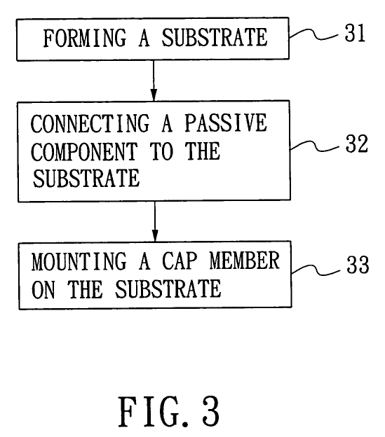

FIG. 3 is a flowchart to illustrate the preferred embodiment of a method for making the pulse transformer package 2 of this invention.

Initially, the substrate 21 that includes the surface layer 211, the base layer 212, the wiring layer 213, the bonding pads 214 and the connecting pads 215 is formed in step 31.

Thereafter, in step 32, the windings 121′ of the passive component 12′ are connected electrically to the bonding pads 214 of the substrate 21.

Finally, in step 33, the cap member 22 is mounted on the surface layer 211 of the substrate 21 such that the cap member 22 cooperates with the surface layer 211 to form a sealed space for the passive component 12′.

In use, the pulse transformer package 2 can be mounted on a circuit board of a communications device (not shown) by applying solder material on the connecting pads 215 so that the pulse transformer package 2 can provide the function of a noise filter.

It is apparent to those skilled in the art that, in practice, the method of the preferred embodiment can further include additional steps, such as appearance inspection, electrical testing, package printing, etc. Since the feature of the present invention does not reside in the specifics of these commonly employed packaging steps, a detailed description of the same will be omitted herein for the sake of brevity.

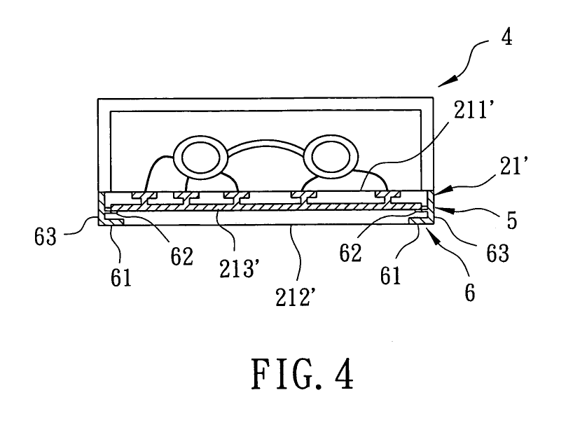

FIG. 4 illustrates the second preferred embodiment of a pulse transformer package 4 according to the present invention, which differs from the previous embodiment in the configuration of the connecting pads 6. In this embodiment, the substrate 21′ has a peripheral surface 5 that extends from the surface layer 211′ to the base layer 212′. Each of the connecting pads 6 includes a first pad segment 61 on the base layer 212′ of the substrate 21′, a second pad segment 62 sandwiched between the surface layer 211′ and the base layer 212′ and connected electrically to one of the wiring tracks of the wiring layer 213′, and a third pad segment 63 on the peripheral surface 5 of the substrate 21′ and connected to the first and second pad segments 61, 62.

In use, the pulse transformer package 4 can be mounted on a circuit board of a communications device (not shown) by applying solder material on the first and/or third pad segments 61, 63so that the pulse transformer package 4 can provide the function of a noise filter. At the same, it is possible to verify whether the pulse transformer package 4 is mounted properly on the circuit board by simply inspecting the presence of the solder material on the third pad segments 63 of the connecting pads 6.

The method for making the pulse transformer package 4 of this embodiment proceeds in a manner similar to that detailed hereinabove in connection with the previous embodiment.

In other embodiments, semiconductor components that do not generate a lot of heat may be incorporated into the pulse transformer package 2, 4 of this invention. After modifying the wiring layers 213, 213′ of the substrates 21, 21′ to take into account the semiconductor components (not shown), both the passive component 12′ and the semiconductor components can be encased within the substrate 21, 21′ and the cap member 22.

In the present invention, the substrate 21, 21′ and the cap member 22 are employed to form a sealed space for the passive component 12′. In view of the planar characteristics of the substrate 21, 21′, the connecting pads 215, 6 on the base layer 212, 212′ can be applied with solder material for mounting the pulse transformer package 2, 4 directly on a circuit board of a communications device. Because the pulse transformer package 2, 4 of this invention does not utilize the stepped terminals of the aforementioned prior art, there is no need to conduct terminal inspection and terminal corrections steps during mass production of the pulse transformer package 2, 4 of this invention, thereby resulting in lower production costs.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A pulse transformer package adapted for mounting on a circuit board to serve as a noise filter, said pulse transformer package comprising:
a substrate including a surface layer, a base layer, and a middle wiring layer between said surface and base layers, each of said surface and base layers being made of a dielectric material,
said substrate further including a set of bonding pads formed on said surface layer, and a set of connecting pads formed on said base layer,
said wiring layer, said bonding pads and said connecting pads being made of an electrically conductive material,
said bonding pads and said connecting pads being connected electrically to said wiring layer,
said connecting pads permitting mounting of said substrate on the circuit board, and being capable of establishing electrical connection between said wiring layer and the circuit board;
a passive component connected electrically to said bonding pads on said substrate, thereby establishing electrical connection between said passive component and said wiring layer; and
a cap member connected to said surface layer of said substrate and cooperating with said surface layer to form a sealed space for said passive component.

2. The pulse transformer package as claimed in claim 1, wherein each of said connecting pads extends into said base layer to connect electrically with said wiring layer.

3. The pulse transformer package as claimed in claim 1, wherein said substrate has a peripheral surface that extends from said surface layer to said base layer, each of said connecting pads including
a first pad segment on said base layer of said substrate,
a second pad segment between said surface layer and said base layer, and connected electrically to said wiring layer, and
a third pad segment on said peripheral surface of said substrate, and connected to said first and second pad segments.

4. The pulse transformer package as claimed in claim 1, wherein said passive component includes a plurality of windings connected electrically to said bonding pads.

5. The pulse transformer package as claimed in claim 1, wherein said cap member includes a cover part and a surrounding wall part that has opposite ends connected to said surface layer of said substrate and said cover part, respectively.

6. A method for making a pulse transformer package that is suitable for mounting on a circuit board, comprising the steps of:
a) forming a substrate that includes a surface layer, a base layer, and a middle wiring layer between the surface and base layers, each of the surface and base layers being made of a dielectric material,
the substrate further including a set of bonding pads formed on the surface layer, and a set of connecting pads formed on the base layer,
the wiring layer, the bonding pads and the connecting pads being made of an electrically conductive material,
the bonding pads and the connecting pads being connected electrically to the wiring layer,
the connecting pads permitting mounting of the substrate on the circuit board, and being capable of establishing electrical connection between the wiring layer and the circuit board;
b) connecting a passive component electrically to the bonding pads on the substrate, thereby establishing electrical connection between the passive component and the wiring layer; and
c) mounting a cap member on the surface layer of the substrate such that the cap member cooperates with the surface layer to form a sealed space for the passive component.

7. The method as claimed in claim 6, wherein, in step a), each of the connecting pads extends into the base layer to connect electrically with the wiring layer.

8. The method as claimed in claim 6, wherein, in step a), the substrate has a peripheral surface that extends from the surface layer to the base layer, and each of the connecting pads includes
a first pad segment on the base layer of the substrate,
a second pad segment between the surface layer and the base layer, and connected electrically to the wiring layer, and
a third pad segment on the peripheral surface of the substrate, and connected to the first and second pad segments.
